(19) United States
(12) Patent Application Publication
(10) Pub. No.: US 2026/0198087 A1
(43) Pub. Date: Jul. 9, 2026

(54) METHODS OF FORMING DIELECTRIC FEATURES IN STACKED TRANSISTORS

(71) Applicant: Taiwan Semiconductor Manufacturing Co., Ltd., Hsinchu (TW)

(72) Inventors: Shun-Hsien Pan, Kaohsiung City (TW); Chung-Ting Ko, Kaohsiung City (TW); Zhi-Chang Lin, Zhubei City (TW)

(21) Appl. No.: 19/013,730

(22) Filed: Jan. 8, 2025

(51) Int. Cl. H10D 84/85; H10D 84/01

(52) U.S. Cl. CPC H10D 84/856; H10D 84/017; H10D 84/0188; H10D 84/851

(57) ABSTRACT

A semiconductor device and the method of forming the same are provided. The semiconductor device may include a first nanostructure, a first gate structure around the first nanostructure, a second nanostructure, a second gate structure around the second nanostructure, a first dielectric feature between the first nanostructure and the second nanostructure, and a first dielectric layer. The first dielectric layer may be between the first nanostructure and the first dielectric feature. The first dielectric layer may be between the second nanostructure and the first dielectric feature. The first dielectric feature may comprise a first material and the first dielectric layer may comprise a second material different from the first material. The first dielectric feature may comprise a first dielectric sublayer comprising the first material and a second dielectric sublayer comprising the first material. A physical interface may be between the first dielectric sublayer and the second dielectric sublayer.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5, 6A, 6B, 6C, 6D, 7A, 7B, 8A, 8B, 9, 10, 11A, and 11B are various views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising an upper transistor and a lower transistor that are vertically stacked. Each of the upper and lower transistors may include gate structures wrapping around respective semiconductor nanostructures and source/drain regions on sidewalls of the respective semiconductor nanostructures. In certain regions of the semiconductor device, spaces under the source/drain region or spaces between the source/drain regions may be filled with dielectric features. By forming the dielectric features using methods comprising a sequence of repeated formation cycles, each of which may include a deposition step, a plasma treatment step, and an etching step, structural integrity of dummy gate layers may be maintained. Since the dummy gate layers may be then replaced by the gate structures, selected shapes and sizes of the gate structures may be better defined by maintaining the integrity of the dummy gate layers. As a result, the performance and reliability of the stacking transistor may be improved.

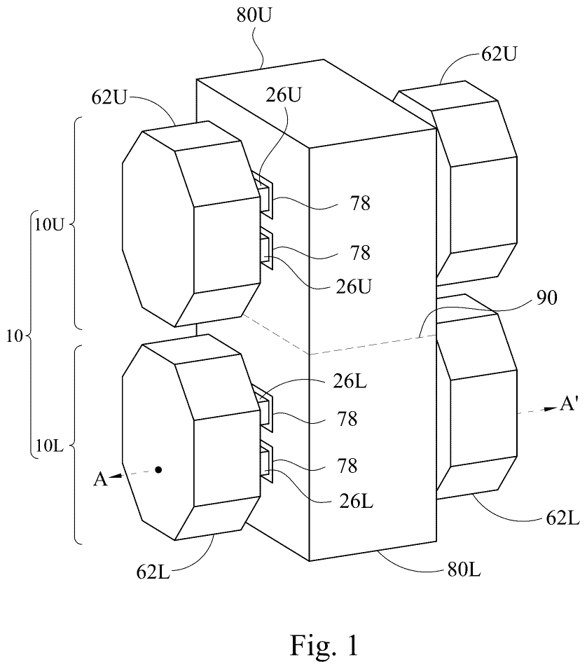

FIG. 1 illustrates an example of a stacking transistor 10 (including Field Effect Transistors (FETs) 10U and 10L) in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors, Nano Field-effect Transistors (nano-FETs), Fin Field Effect Transistors (finFETs), or the like.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A′, which is a vertical cross-section that is parallel to a longitudinal axis of the semiconductor nanostructures 26 of a stacking transistor and in a direction of, for example, a current flow between the source/drain regions 62 of the stacking transistor. Subsequent figures may refer to reference cross-section A-A′ for clarity.

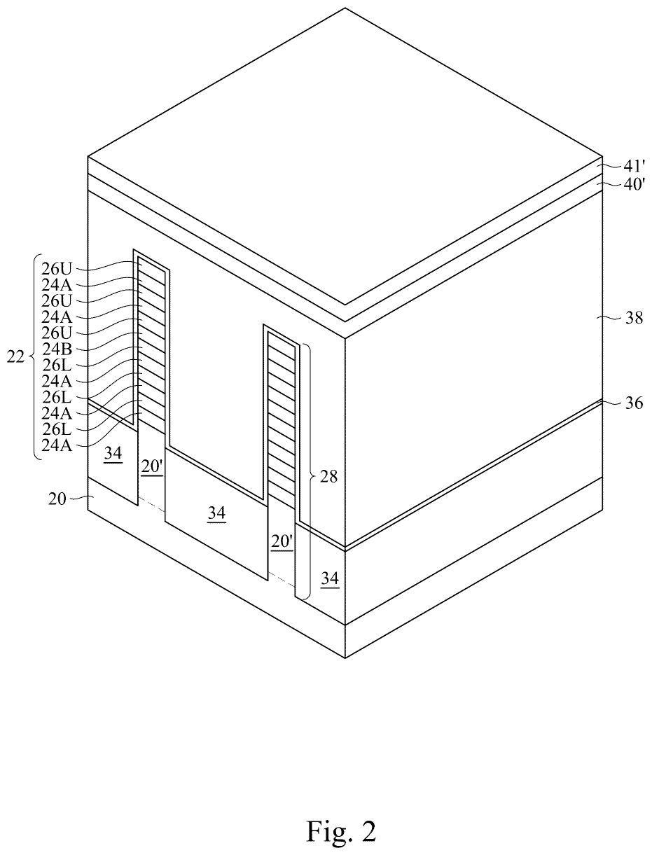

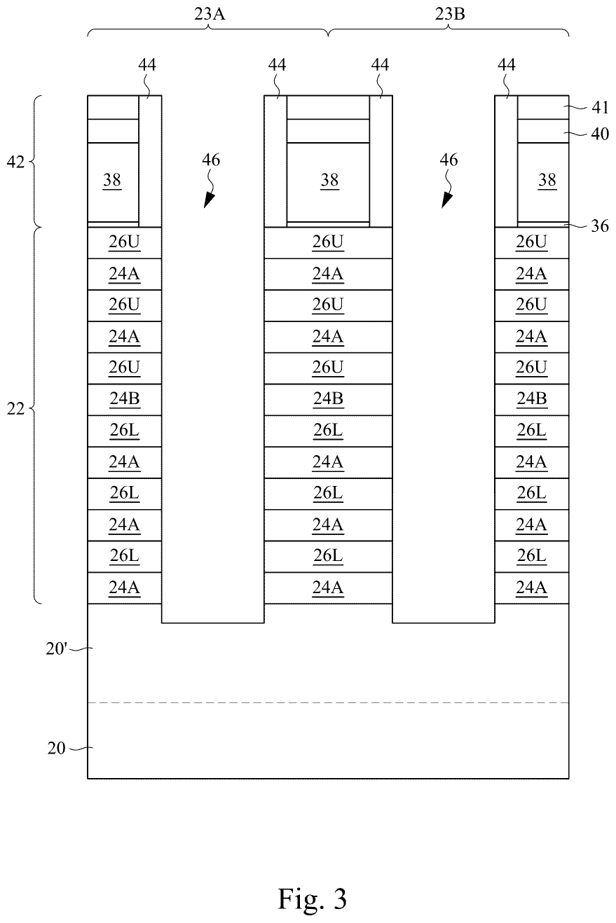

FIGS. 2 through 11B are various views of intermediate stages in the manufacturing of a stacking transistor, which is similar to the one shown in FIG. 1, in accordance with some embodiments. FIG. 2 is a perspective view and FIGS. 3 through 11 are cross-sectional views of a portion of the structure shown in FIG. 2 along a reference cross-section similar to the reference cross-section A-A′ as shown in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the substrate 20. Each of semiconductor strips 28 includes semiconductor fin 20′ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will act as channel regions for lower nanostructure-FETs of the stacking transistor. The upper semiconductor nanostructures 26U will act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20′, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 34 are formed over the substrate 20 and between adjacent semiconductor strips 28. STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric layers(s) are recessed to define the STI regions 34. The dielectric layer(s) maybe recessed such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like.

A first mask layer 40′ is formed over the planarized dummy gate layer 38 and a second mask layer 41′ is formed on the first mask layer 40′. The first mask layer 40′ may include, silicon nitride, silicon oxynitride, or the like. The second mask layer 41′ may include, silicon oxide or the like. Then the first mask layer 40′ and the second mask layer 41′ may be patterned by photolithography and etching processes to form a first mask 40 and a second mask 41 (see FIG. 3), which may be then used to pattern dummy gate layer 38 and the dummy dielectric layer 36. The first mask 40, the second mask 41, and the remaining portions of dummy gate layer 38, and dummy dielectric layer 36 may be referred to as the dummy gate stacks 42.

In FIG. 3, gate spacers 44 and source/drain recesses 46 are formed. The structure shown in FIG. 3 may comprise a region 23A and a region 23B, each of which includes one source/drain recess 46. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The first mask 40, the second mask 41, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20′. The bottom surfaces of the source/drain recesses 46 may be at a level above, below, or level with the top surfaces of the STI regions 34. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

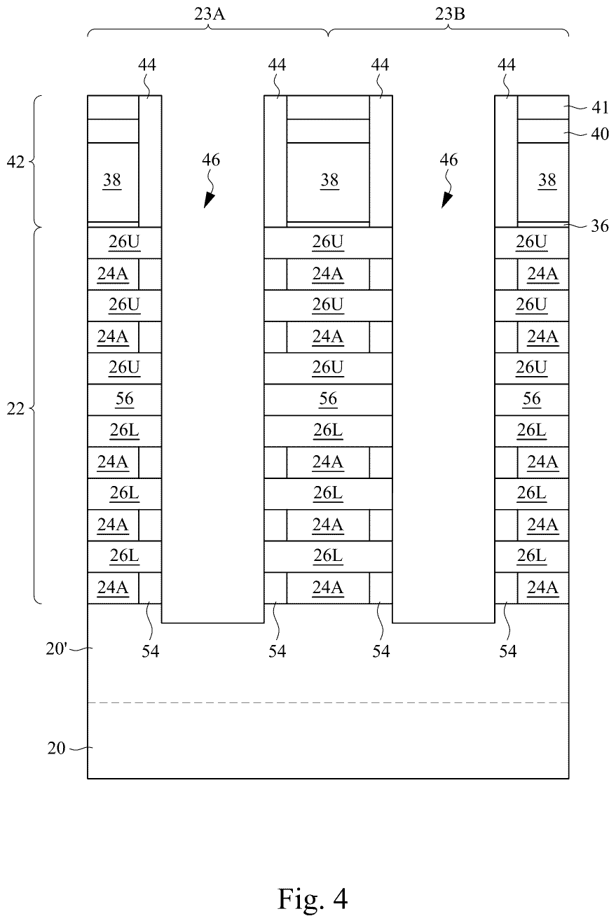

In FIG. 4, the dummy nanostructures 24A are partially removed and the dummy nanostructure 24B are completely removed. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20′. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on the sidewalls the dummy nanostructures 24A, and between the bottom upper semiconductor nanostructures 26U and the top lower semiconductor nanostructures 26L. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

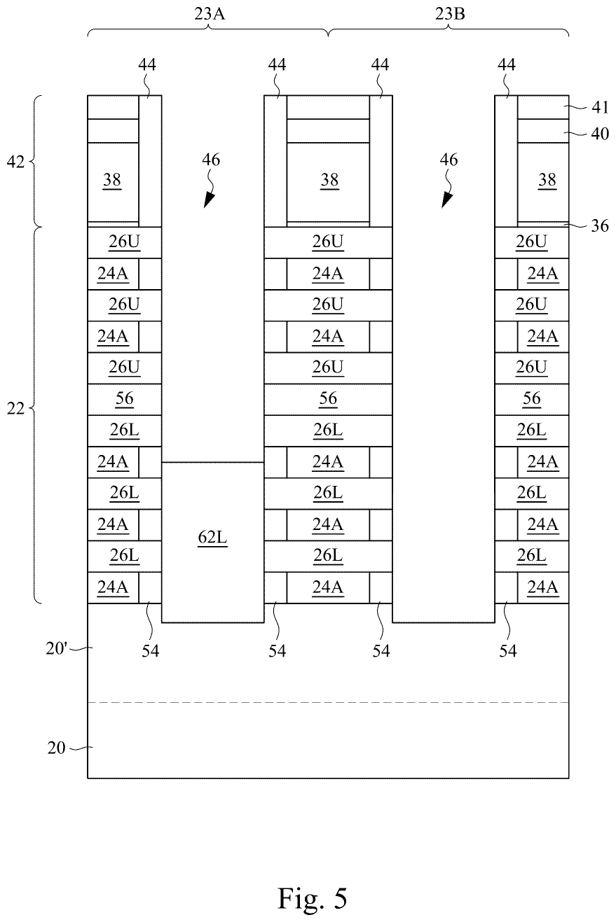

In FIG. 5, the lower epitaxial source/drain region 62L is formed on bottoms of the source/drain recesses 46 in the region 23A. The lower epitaxial source/drain region 62L may be formed on the semiconductor fin 20′ in the lower portion of the source/drain recess 46. The lower epitaxial source/drain region 62L may be in contact with the lower semiconductor nanostructures 26L and not in contact with the upper semiconductor nanostructures 26U. The lower epitaxial source/drain region 62L may be in contact with the inner spacers 54, which electrically insulate the lower epitaxial source/drain region 62L from the dummy nanostructures 24A. The lower epitaxial source/drain region 62L may be epitaxially grown from exposed surfaces of the lower semiconductor nanostructures 26L and the semiconductor fin 20′ in the region 23A. The lower epitaxial source/drain region 62L may have a conductivity type that is suitable for the device type (p-type or n-type) of the lower nanostructure-FETs. When the lower epitaxial source/drain region 62L is an n-type source/drain region, the respective material may include silicon or carbon-doped silicon, which is doped with an n-type dopant such as phosphorous, arsenic, or the like. When the lower epitaxial source/drain region 62L is a p-type source/drain region, the respective material may include silicon or silicon germanium, which is doped with a p-type dopant such as boron, indium, or the like. The lower epitaxial source/drain region 62L may be in-situ doped, and may be, or may not be, implanted with the corresponding p-type or n-type dopants.

During the formation of the lower epitaxial source/drain region 62L in the region 23A, exposed surfaces of the upper semiconductor nanostructures 26U (e.g., sidewalls) in the region 23A as well as exposed surfaces of the semiconductor nanostructures 26 (e.g., sidewalls) and the semiconductor fin 20′ (e.g., top surface) in the region 23B may be masked to prevent undesired epitaxial growth on the said exposed surfaces. After the lower epitaxial source/drain region 62L is formed in the region 23A, the said masks may then be removed.

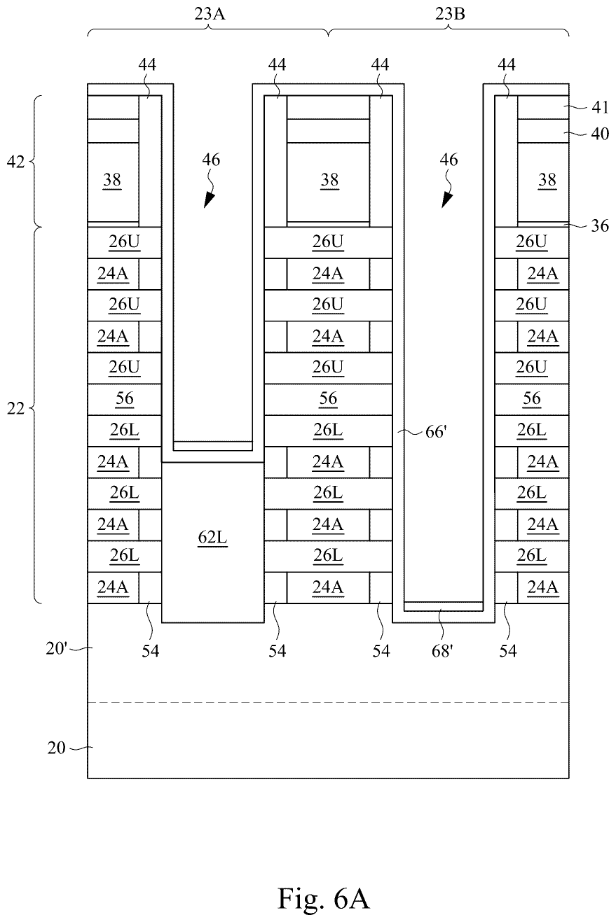

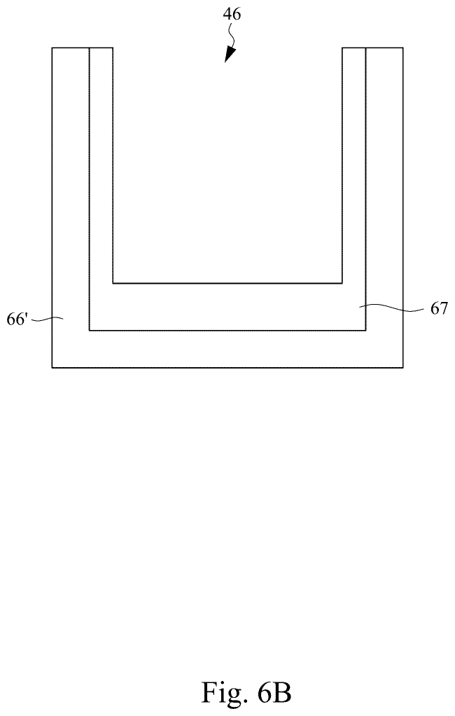

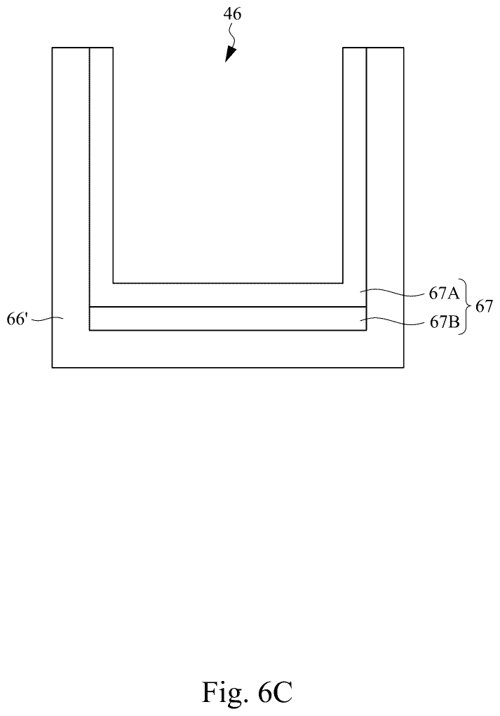

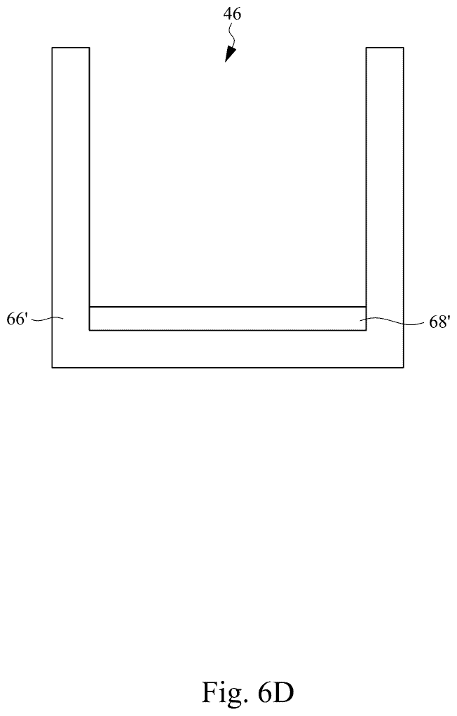

In FIG. 6A, a dielectric layer 66′ is formed on top surfaces of the second mask 41, the gate spacers 44 and surfaces exposed by the source/drain recesses 46, and dielectric sublayers 68′ are formed on lower portions of the dielectric layer 66′ in the source/drain recesses 46. The dielectric layer 66′ may be subsequently patterned to form Contact Etch Stop Layers (CESLs). The dielectric sublayers 68′ may be parts of subsequently formed Inter-Layer Dielectrics (ILDs). In the region 23A, the lower portion of the dielectric layer 66′ may be in contact with the lower epitaxial source/drain region 62L. In the region 23B, the lower portion of the dielectric layer 66′ may be in contact with the semiconductor fin 20'. The dielectric layer 66′ may be formed of silicon nitride, silicon oxycarbide, or the like and may be formed by a suitable deposition process, such as CVD, ALD, or the like. In some embodiments, the dielectric layer 66′ comprises a different material from the gate spacers 44 and the inner spacers 54. The dielectric layer 66′ and the dielectric sublayers 68′ may comprise different materials. The dielectric sublayers 68′ may be formed of a dielectric material having a high etching selectivity to the material of the dielectric layer 66′, such as silicon oxide, silicon nitride, or the like. As a result, handling involved in forming the dielectric sublayers 68′ may be reduced, which may improve the structural integrity and reliability of the subsequently formed stacking transistor.

FIGS. 6B, 6B, and 6D use a portion of the structure shown in FIG. 6A to illustrate various steps of a formation process of the dielectric sublayers 68′ in the region 23A or the region 23B. The formation process may comprise a deposition step as shown in FIG. 6B, a plasma treatment step as shown in FIG. 6C, and an etching step as shown in FIG. 6D, which may be completed sequentially in a same process chamber between each of the deposition step, the plasma treatment step, or the etching step (e.g., in situ).

In the deposition step as shown in FIG. 6B, a dielectric layer 67 comprising the material of the dielectric sublayer 68′ may be formed by a suitable deposition process, such as CVD or the like, which may cover surfaces of the dielectric layer 66′. A bottom portion of the dielectric layer 67 on a bottom portion of the dielectric layer 66′ may have a larger thickness than other portions of the dielectric layer 67. In the plasma treatment step as shown in FIG. 6C, a suitable plasma, such as oxygen plasma, nitrogen plasma, or the like, may be used to treat the dielectric layer 67. By controlling a frequency of a source that generates the plasma, a portion of the dielectric layer 67 may be treated by the plasma and converted to a treated dielectric layer 67A. The bottom portion of the dielectric layer 67 may be partially treated due to the larger thickness. The untreated portion of the dielectric layer 67 in contact with the bottom portion of the dielectric layer 66′ may be referred to as an untreated dielectric layer 67B. The treated dielectric layer 67A may comprise a different material from the untreated dielectric layer 67B and the dielectric layer 66′, which may result in the treated dielectric layer 67A having an etching selectivity to the untreated dielectric layer 67B and the dielectric layer 66′. In the etching step as shown in FIG. 6D, a suitable etching process, such as a drying etching process or the like, may be used to selectively remove the treated dielectric layer 67A. The untreated dielectric layer 67B may remain substantially intact after the etching step and may be referred to as the dielectric sublayer 68′. The dielectric layer 66′ may remain substantially intact after the etching step as well. The etching step may include using hydrofluoric acid, hydrogen, or the like may be used as an etchant. The etching time may be short and in a range from about 1 second to about 10 seconds.

In some embodiments, the dielectric layer 67 comprises silicon oxide and the dielectric layer 66′ comprises silicon nitride. After treating the dielectric layer 67 with nitrogen plasma, the treated dielectric layer 67A comprising silicon oxynitride is generated, while the untreated dielectric layer 67B remains a silicon oxide material. For example, the untreated dielectric layer 67B may be substantially free of nitrogen or have a lower concentration of nitrogen than the treated dielectric layer 67A. As a result, the treated dielectric layer 67A has an etching selectivity to the untreated dielectric layer 67B and the dielectric layer 66′, and the treated dielectric layer 67A is selectively removed in the subsequent etching step. In some embodiments, the dielectric layer 67 comprises silicon nitride and the dielectric layer 66′ comprises silicon oxycarbide. After treating the dielectric layer 67 with oxygen plasma, the treated dielectric layer 67A comprising silicon oxynitride is generated, while the untreated dielectric layer 67B remains a silicon nitride material. For example, the untreated dielectric layer 67B may be substantially free of oxygen or have a lower concentration of oxygen than the treated dielectric layer 67A. As a result, the treated dielectric layer 67A has an etching selectivity to the untreated dielectric layer 67B and the dielectric layer 66′, and the treated dielectric layer 67A is selectively removed in the subsequent etching step.

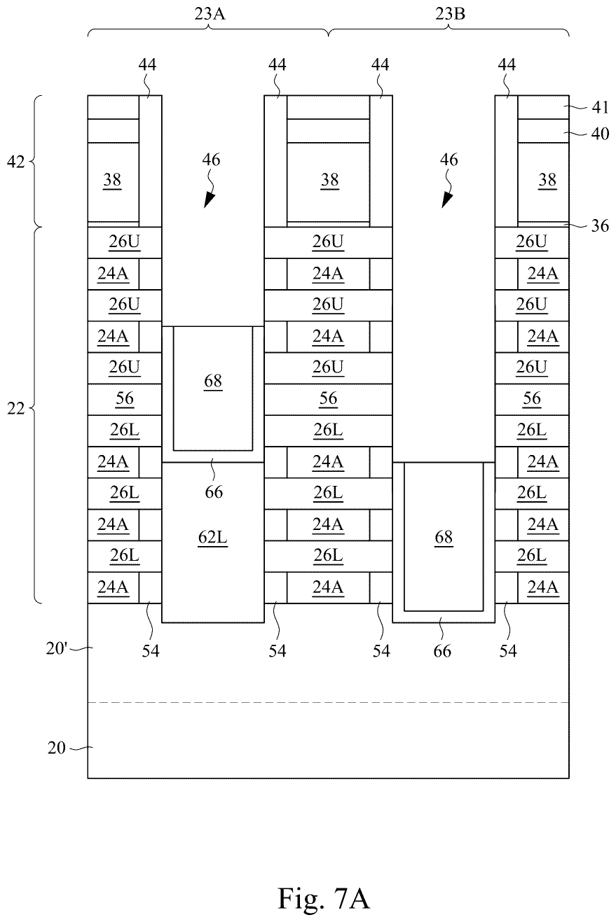

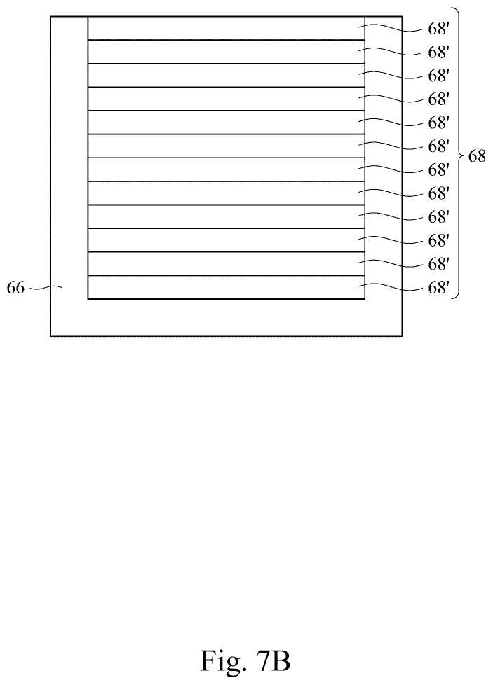

In FIG. 7A, first ILDs 68 and first CESLs 66 are formed in the source/drain recesses 46. The first ILDs 68 in the region 23A and the region 23B may be simultaneously formed by repeating the process of forming the dielectric sublayers 68′ described above with respect to FIGS. 6A-6D by a selected number of times. As a result, the first ILDs 68 in the region 23A and the region 23B may comprise the selected number of the dielectric sublayers 68′, each having a same thickness. The first ILDs 68 the region 23A and the region 23B may have a same thickness. The repeated process of forming the dielectric sublayers 68′ may be also referred to as a formation cycle. The selected number of formation cycles in forming the first ILDs 68 may be performed in the same process chamber between each of the formation cycles (e.g., in situ). As a result, handling involved in forming the first ILDs 68 may be reduced, which may improve the structural integrity and reliability of the subsequently formed stacking transistor. Then first CESLs 66 may be formed by removing the portions of the dielectric layer 66′ not covered by the first ILDs 68. The removal may be done by a suitable etching process, such as a wet etching process. After the removal, the remaining portions of the dielectric layer 66′ may be referred to as the first CESLs 66. After the removal, the sidewalls of the upper semiconductor nanostructures 26U may be exposed.

Due to the formation methods of the first ILDs 68 and the first CESLs 66 described above with respect to FIGS. 6A through 7A, the first mask 40, the second mask 41, and the gate spacers 44 may be exposed to etchants for a reduced amount of time during the various etching processes due to the short etching time of the etching steps during the formation of the first ILDs 68. Further, a need for a planarization process, such as CMP or the like, during the formation of the first ILDs 68 and the first CESLs 66 may be eliminated. Therefore, the first mask 40, the second mask 41, and the gate spacers 44 may not be exposed to any polishing chemical during the formation of the first ILDs 68 and the first CESLs 66. Therefore, the structural integrity of the first mask 40, the second mask 41, and the gate spacers 44 may be maintained, which may result in sufficient protection of the dummy gate layers 38 during the formation of the first ILDs 68 and the first CESLs 66.

FIG. 7B shows the first ILD 68 and the first CESL 66 with more structural details in accordance to some embodiments. The first ILD 68 may comprise a plurality of the dielectric sublayers 68′ with distinctive physical interfaces between neighboring dielectric sublayers 68′. Each of the dielectric sublayers 68′may have a same thickness. The quantity of the dielectric sublayers 68′ shown in FIG. 7B is provided as an example. The first CESL 66 may have a shape of a “U”. The first CESL 66 may be in contact with a bottom surface and sidewalls of the first ILD 68. The first CESL 66 may be in contact with sidewalls of the dielectric sublayers 68′.

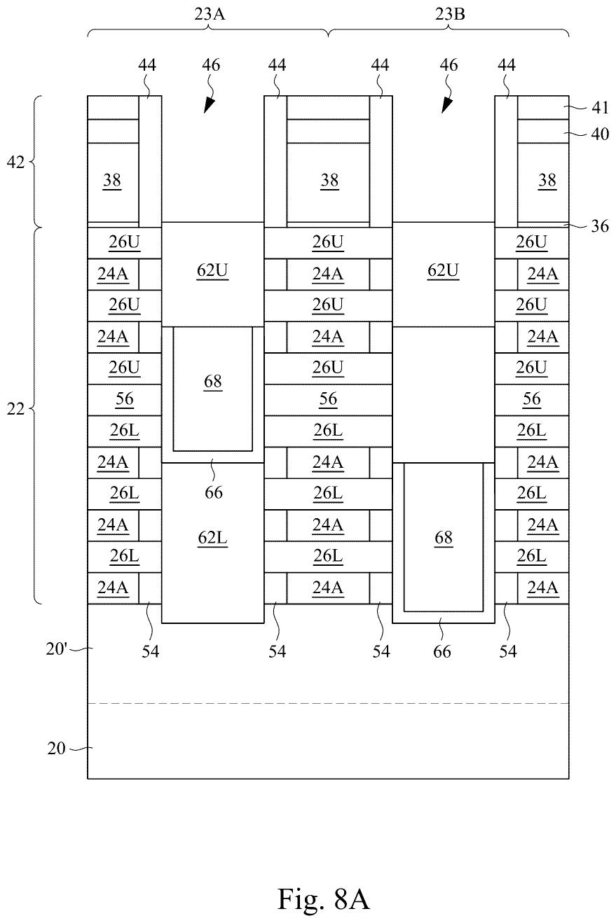

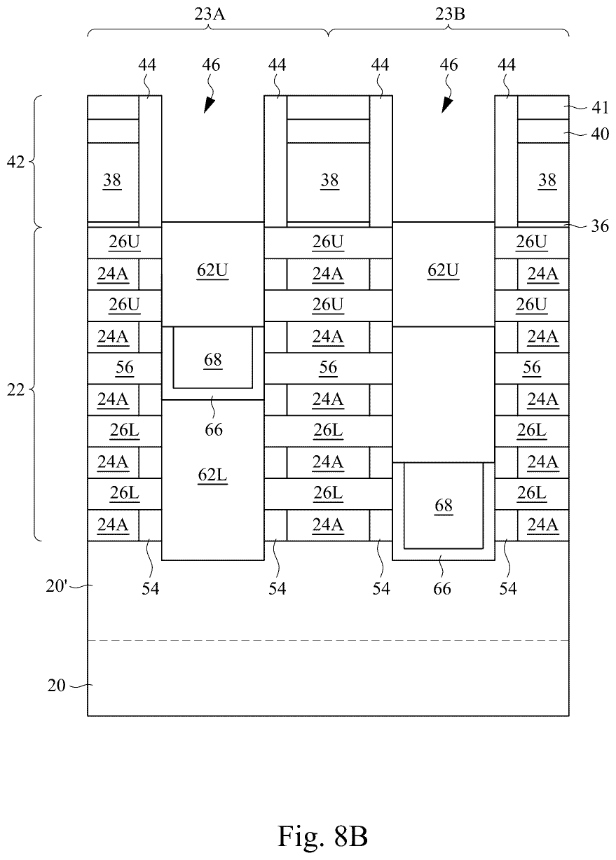

In FIG. 8A, the upper epitaxial source/drain regions 62U are formed in the upper portions of the source/drain recesses 46 in the region 23A and the region 23B. The upper epitaxial source/drain regions 62U may be in contact with the upper semiconductor nanostructures 26U and not in contact with the lower semiconductor nanostructures 26L. The upper epitaxial source/drain regions 62U may be in contact with the inner spacers 54, which electrically insulate the upper epitaxial source/drain regions 62U from the dummy nanostructures 24A. In the region 23A, the upper epitaxial source/drain region 62U may be in contact with the first ILD 68 and the first CESL 66. In the region 23B, the upper epitaxial source/drain region 62U may be separated from the first ILD 68 and the first CESL 66, and an air gap may be between the upper epitaxial source/drain region 62U and the first ILD 68.

The upper epitaxial source/drain regions 62U may be epitaxially grown from exposed surfaces of the upper semiconductor nanostructures 26U. The materials of the upper epitaxial source/drain regions 62U may be selected from the same candidate group of materials for forming the lower epitaxial source/drain region 62L, depending on the selected conductivity type of upper epitaxial source/drain regions 62U. The conductivity type of the upper epitaxial source/drain regions 62U may be opposite the conductivity type of the lower epitaxial source/drain region 62L in embodiments where the stacking transistors are CFETs. For example, the upper epitaxial source/drain regions 62U may be oppositely doped from the lower epitaxial source/drain region 62L. Alternatively, the conductivity types of the upper epitaxial source/drain regions 62U and the lower epitaxial source/drain region 62L may be the same. The upper epitaxial source/drain regions 62U may be in-situ doped, and/or may be implanted, with an n-type or p-type dopant.

During the formation of the upper epitaxial source/drain regions 62U, exposed sidewalls of the lower semiconductor nanostructures 26L and the upper semiconductor nanostructures 26U in contact with the dielectric isolation layers 56 in the region 23B may be masked to prevent undesired epitaxial growth on the said exposed sidewalls. After the upper epitaxial source/drain regions 62U are formed, the said masks may then be removed. FIG. 8A shows one cross-section of the structure as an example, other cross-sections of the same structure may be different from the one shown in FIG. 8A, and a space between the upper epitaxial source/drain region 62U and the first ILD 68 in the region 23B may be accessible from the other cross-sections.

FIG. 8B shows a structure similar to the one shown in FIG. 8A, in accordance with some embodiments, wherein like numerals refer to like features formed by like processes. In the structure shown in FIG. 8B, the dielectric isolation layers 56 may be between and in contact with neighboring dummy nanostructures 24A and the corresponding inner spacers 54. In the region 23A, the first CESL 66 may be in contact with the inner spacers 54 and the dielectric isolation layers 56, and separated from the semiconductor nanostructures 26. In the region 23B, the first CESL 66 may be in contact with the inner spacers 54 and the lower semiconductor nanostructures 26L. The first ILDs 68 the region 23A and the region 23B may have a same thickness.

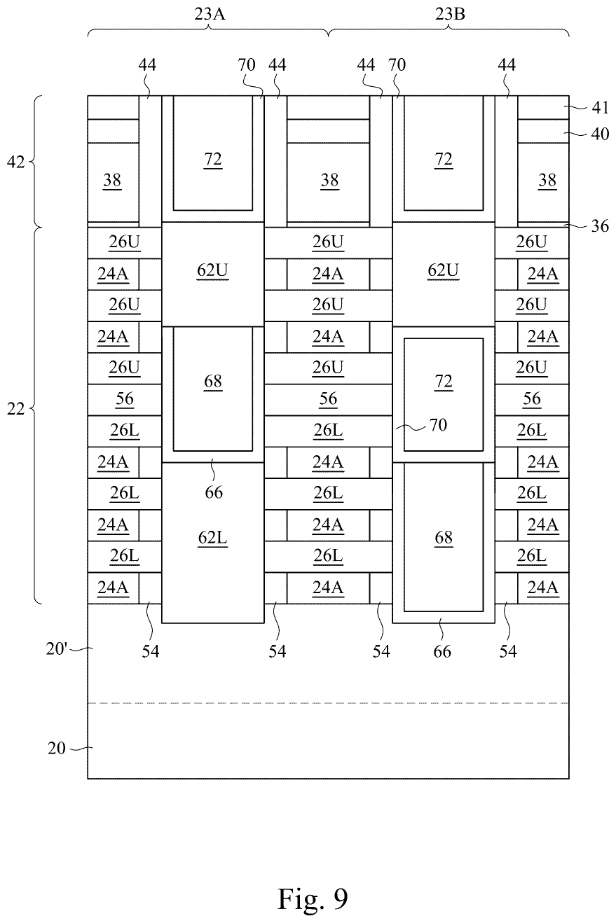

In FIG. 9, second CESLs 70 and second ILDs 72 are formed in the source/drain recesses 46. In the region 23A, the second CESL 70 may be formed on a top surface of the upper epitaxial source/drain region 62U and sidewalls of the gate spacers 44, and the second ILD 72 may be formed on the second CESL 70. In the region 23B, the second CESL 70 may comprise two portions and the second ILD 72 may comprise two portions. A first portion of the second CESL 70 may be formed on a top surface of the upper epitaxial source/drain region 62U and sidewalls of the gate spacers 44, and a first portion of the second ILD 72 may be formed on the first portion of the second CESL 70. A second portion of the second CESL 70 may be formed in the space between the upper epitaxial source/drain region 62U and the first ILD 68 in the region 23B. The second portion of the second CESL 70 may be in contact with a bottom surface of the upper epitaxial source/drain region 62U, top surfaces of the first ILD 68 and the first CESL 66, and sidewalls of the inner spacers 54, the dielectric isolation layers 56, the upper semiconductor nanostructures 26U, and the lower semiconductor nanostructures 26L. The second portion of the second CESL 70 may have a shape of a frame. The second portion of the second ILD 72 may be formed on (e.g., within) the second portion of the second CESL 70 and may be encircled (e.g., surrounded) by the second portion of the second CESL 70 in the cross-sectional view.

The second CESLs 70 may be formed of a same or similar material and formed by a same or similar process as the first CESL 66. The second ILDs 72 may be formed of a same or similar material as the first ILDs 68. The second CESLs and the second ILDs 72 may comprise different materials. The materials of the second CESLs may have a high etching selectivity to the material of and the second ILDs 72. The second ILDs 72 in the region 23A and the region 23B may be formed simultaneously by a suitable deposition process, such as FCVD or the like. The FCVD process may comprise a deposition step, a curing step, and an annealing step. After the second CESLs 70 and the second ILDs 72 are formed, a planarization process, such as CMP or the like, may be performed to level top surfaces of the second masks 41, the second CESLs 70, and the second ILDs 72.

After the second CESL 70 and second ILD 72 are formed in the region 23B, a space between the upper epitaxial source/drain region 62U and the semiconductor fin 20′ in the region 23B may be filled by the first ILD 68, the first CESL 66, the second ILD 72, and the second CESL 70. Due the formation methods of the first ILD 68, the first CESL 66, the second ILD 72, and the second CESL 70 described above with respect to FIGS. 6A, 7A, and 9, the first mask 40, the second mask 41, and the gate spacers 44 may be exposed to etchants and polishing chemicals by a reduced amount of time during the processes performed to form the first ILD 68, the first CESL 66, the second ILD 72, and the second CESL 70. Therefore, the structural integrity of the first mask 40, the second mask 41, and the gate spacers 44 may be maintained, which may result in sufficient protection of the dummy gate layers 38 during the said processes. As a result, the structural integrity of the dummy gate layers 38 may be maintained, thereby leading to selected shapes and sizes of subsequently formed gate structures.

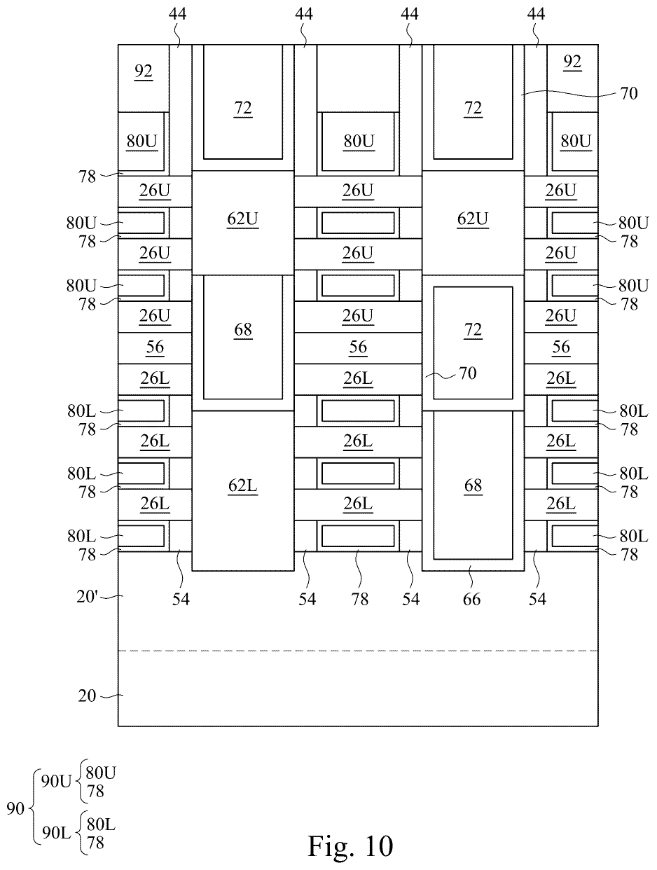

In FIG. 10, a gate replacement process to replace the dummy gate stacks 42 and the dummy nanostructures 24A with gate structures 90 is performed. The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the material(s) of the semiconductor nanostructures 26. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

Then, gate dielectrics 78 may be deposited in the recesses between the gate spacers 44 and on the exposed semiconductor nanostructures 26. The gate dielectrics 78 may be conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the inner spacers 54.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the lower semiconductor nanostructures 26L. The lower gate electrodes 80L may wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Upper gate electrodes 80U may be formed on the isolation layers described above (if present) or the lower gate electrodes 80L. The upper gate electrodes 80U may be disposed between the upper semiconductor nanostructures 26U. In some embodiments, the upper gate electrodes 80U wrap around the upper semiconductor nanostructures 26U. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Gate masks 92 may be formed on the upper gate structures 90U. The formation process may include recessing the upper gate structures 90U, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72 and to level top surfaces of the gate masks 92 and the second ILD 72. The planarization process may be a CMP process, an etch-back process, combinations thereof, or the like. After the planarization process, the top surfaces of the gate masks 92, the gate dielectrics 78, the second ILD 72, and the gate spacers 44 may be substantially coplanar (within process variations). In some embodiments, gate masks are 92 not formed, and after the planarization process, the top surfaces of the upper gate electrodes 80U, the gate dielectrics 78, the second ILD 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

Due the methods of forming the first ILD s68 and the first CESLs 66 in the region 23A and the region 23B described above with respect to FIGS. 6A, 7A, and 9, the dummy gate layers 38 may be sufficiently protected and the structural integrity of the dummy gate layers 38 may be maintained, which may lead to the selected shapes and sizes of the gate structures 90. As a result, the performance and reliability of the subsequently formed stacking transistor may be improved.

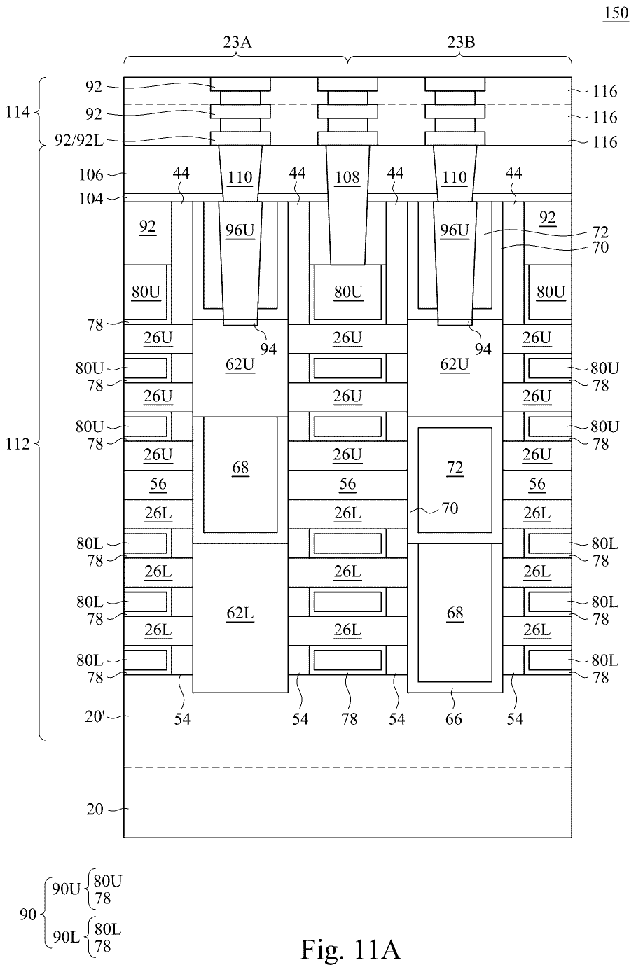

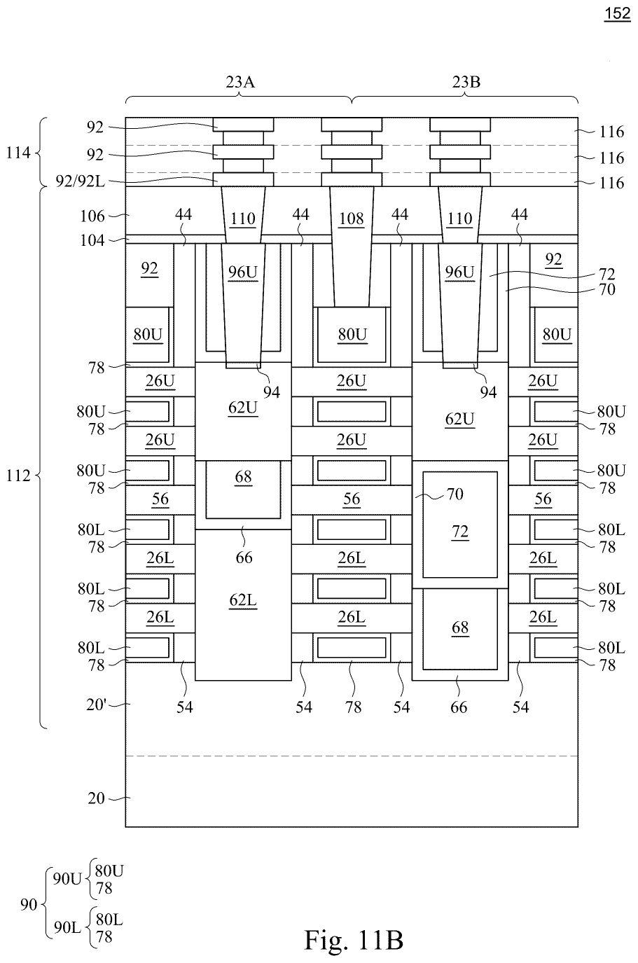

In FIG. 11A, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the device layer 112 (e.g., a side opposite to the front-side interconnect structure 114). The structure shown in FIG. 11A may be referred to as a stacking transistor 150.

FIG. 11B shows a stacking transistor 152 similar to the stacking transistor 150 shown in FIG. 11A, in accordance with some embodiments, wherein like numerals refer to like features formed by like processes. The stacking transistor 152 may be based on the embodiments described with respect to FIG. 8B, and made be formed after the processes described with respect to FIGS. 9 through 11A are performed to the structure shown in FIG. 8B.

The embodiments of the present disclosure have some advantageous features. Due the formation methods of the first ILD 68 and the first CESL 66, the structural integrity of the dummy gate layers 38 may be maintained during the processes performed to form the first ILD 68 and the first CESL 66, which may lead to the selected shapes and sizes of the gate structures 90. As a result, the performance and reliability of the stacking transistor 150 may be improved.

In an embodiment, a semiconductor device includes a first nanostructure; a first gate structure around the first nanostructure; a second nanostructure; a second gate structure around the second nanostructure; a first dielectric feature between the first nanostructure and the second nanostructure, wherein the first dielectric feature includes a first material, wherein the first dielectric feature includes a first dielectric sublayer including the first material and a second dielectric sublayer including the first material, and wherein a physical interface is between the first dielectric sublayer and the second dielectric sublayer; and a first dielectric layer, wherein the first dielectric layer is between the first nanostructure and the first dielectric feature, wherein the first dielectric layer is between the second nanostructure and the first dielectric feature, and wherein the first dielectric layer includes a second material different from the first material. In an embodiment, the first dielectric layer is in contact with sidewalls of the first dielectric sublayer, and wherein the first dielectric layer is in contact with sidewalls of the second dielectric sublayer. In an embodiment, the semiconductor device further includes a second dielectric feature over the first dielectric feature; and a second dielectric layer, wherein the second dielectric layer is between the first dielectric feature and the second dielectric feature, and wherein the second dielectric feature and the second dielectric layer include different materials. In an embodiment, the second dielectric layer encircles the second dielectric feature in a cross-sectional view. In an embodiment, the semiconductor device further includes an isolation feature over the first nanostructure, wherein in the isolation feature is in contact with the second dielectric layer. In an embodiment, the semiconductor device further includes a first source/drain region in contact with the second dielectric layer. In an embodiment, the semiconductor device further includes a first source/drain region in contact with the first nanostructure.

In an embodiment, a method of forming a semiconductor device includes forming a first nanostructure; forming a first opening; depositing a first dielectric layer in the first opening, wherein the first dielectric layer is in contact with the first nanostructure; depositing a first dielectric feature in the first opening and on the first dielectric layer, wherein the first dielectric layer and the first dielectric feature include different materials, wherein depositing the first dielectric feature includes performing a plurality of formation cycles, wherein each of the plurality of formation cycles forms a dielectric sublayer of the first dielectric feature, and wherein the first dielectric feature includes physical interfaces between neighboring dielectric sublayers of the first dielectric feature; and forming a first gate structure around the first nanostructure. In an embodiment, each of the plurality of formation cycles includes a chemical vapor deposition (CVD) process. In an embodiment, the method further includes forming a second dielectric layer in the first opening and on the first dielectric feature and the first dielectric layer; and forming a second dielectric feature in the first opening, wherein the second dielectric layer surround the second dielectric feature in a cross-sectional view. In an embodiment, forming the second dielectric feature includes performing a flowable chemical vapor deposition (FCVD) process. In an embodiment, the second dielectric layer and the second dielectric feature include different materials. In an embodiment, the method further includes forming a second opening and forming a first source/drain region in the second opening, wherein the first source/drain region is in contact with the first nanostructure. In an embodiment, method further includes forming a third dielectric layer in the second opening and on the first source/drain region, wherein the third dielectric layer and the first dielectric layer are formed by a same process; and forming a third dielectric feature in the second opening and on the third dielectric layer, wherein the third dielectric feature and the first dielectric feature are formed by a same process.

In an embodiment, a method of forming a semiconductor device includes forming a first nanostructure; forming a first opening and a second opening, wherein the first nanostructure is between the first opening and the second opening; growing a first source/drain region in the first opening, wherein the first source/drain region is in contact with a first sidewall of the first nanostructure; depositing a first dielectric layer in the first opening and a second dielectric layer in the second opening, wherein the first dielectric layer is in contact with the first source/drain region, and wherein the second dielectric layer is in contact with a second sidewall of first nanostructure; depositing a first dielectric feature in the first opening and on the first dielectric layer and a second dielectric feature in the second opening and on the second dielectric layer; and growing a second source/drain region in the first opening and a third source/drain region in the second opening, wherein the second source/drain region is in contact with the first dielectric feature, and wherein the third source/drain region is separated from the second dielectric feature by an air gap. In an embodiment, the first dielectric layer and the second dielectric layer are formed of a same first material and by a same first process, and wherein the first dielectric feature and the second dielectric feature are formed of a same second material and by a same second process. In an embodiment, the first dielectric feature includes a first plurality of dielectric sublayers with first physical interfaces between neighboring dielectric sublayers of the first plurality of dielectric sublayers, wherein the second dielectric feature includes a second plurality of dielectric sublayers with second physical interfaces between neighboring dielectric sublayers of the second plurality of dielectric sublayers, and wherein the first plurality of dielectric sublayers and the second plurality of dielectric sublayers include the second material. In an embodiment, the method further includes forming a third dielectric layer in the second opening, wherein the third dielectric layer is in contact with the third source/drain region and the second dielectric feature; and forming a third dielectric feature on the third dielectric layer, wherein the third dielectric layer encircles the third dielectric feature in a cross-sectional view. In an embodiment, the method further includes forming a second nanostructure over the first nanostructure, wherein an isolation feature is between the second nanostructure and the first nanostructure, wherein the second source/drain region is in contact with a first sidewall of the second nanostructure, and wherein the third source/drain region is in contact with a second sidewall of the second nanostructure. In an embodiment, the third dielectric layer is in contact with the isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first nanostructure;
a first gate structure around the first nanostructure;
a second nanostructure;
a second gate structure around the second nanostructure;
a first dielectric feature between the first nanostructure and the second nanostructure, wherein the first dielectric feature comprises a first material, wherein the first dielectric feature comprises a first dielectric sublayer comprising the first material and a second dielectric sublayer comprising the first material, and wherein a physical interface is between the first dielectric sublayer and the second dielectric sublayer; and
a first dielectric layer, wherein the first dielectric layer is between the first nanostructure and the first dielectric feature, wherein the first dielectric layer is between the second nanostructure and the first dielectric feature, and wherein the first dielectric layer comprises a second material different from the first material.

2. The semiconductor device of claim 1, wherein the first dielectric layer is in contact with sidewalls of the first dielectric sublayer, and wherein the first dielectric layer is in contact with sidewalls of the second dielectric sublayer.

3. The semiconductor device of claim 1, further comprising:
a second dielectric feature over the first dielectric feature; and
a second dielectric layer, wherein the second dielectric layer is between the first dielectric feature and the second dielectric feature, and wherein the second dielectric feature and the second dielectric layer comprise different materials.

4. The semiconductor device of claim 3, wherein the second dielectric layer encircles the second dielectric feature in a cross-sectional view.

5. The semiconductor device of claim 3, further comprising an isolation feature over the first nanostructure, wherein in the isolation feature is in contact with the second dielectric layer.

6. The semiconductor device of claim 3, further comprising a first source/drain region in contact with the second dielectric layer.

7. The semiconductor device of claim 1, further comprising a first source/drain region in contact with the first nanostructure.

8. A method of forming a semiconductor device, the method comprising:
forming a first nanostructure;
forming a first opening;
depositing a first dielectric layer in the first opening, wherein the first dielectric layer is in contact with the first nanostructure;
depositing a first dielectric feature in the first opening and on the first dielectric layer, wherein the first dielectric layer and the first dielectric feature comprise different materials, wherein depositing the first dielectric feature comprises performing a plurality of formation cycles, wherein each of the plurality of formation cycles forms a dielectric sublayer of the first dielectric feature, and wherein the first dielectric feature comprises physical interfaces between neighboring dielectric sublayers of the first dielectric feature; and
forming a first gate structure around the first nanostructure.

9. The method of claim 8, wherein each of the plurality of formation cycles comprises a chemical vapor deposition (CVD) process.

10. The method of claim 8, further comprising:
forming a second dielectric layer in the first opening and on the first dielectric feature and the first dielectric layer; and
forming a second dielectric feature in the first opening, wherein the second dielectric layer surround the second dielectric feature in a cross-sectional view.

11. The method of claim 10, wherein forming the second dielectric feature comprises performing a flowable chemical vapor deposition (FCVD) process.

12. The method of claim 10, wherein the second dielectric layer and the second dielectric feature comprise different materials.

13. The method of claim 8, further comprising forming a second opening and forming a first source/drain region in the second opening, wherein the first source/drain region is in contact with the first nanostructure.

14. The method of claim 13, further comprising:
forming a third dielectric layer in the second opening and on the first source/drain region, wherein the third dielectric layer and the first dielectric layer are formed by a same process; and
forming a third dielectric feature in the second opening and on the third dielectric layer, wherein the third dielectric feature and the first dielectric feature are formed by a same process.

15. A method of forming a semiconductor device, the method comprising:
forming a first nanostructure;
forming a first opening and a second opening, wherein the first nanostructure is between the first opening and the second opening;
growing a first source/drain region in the first opening, wherein the first source/drain region is in contact with a first sidewall of the first nanostructure;
depositing a first dielectric layer in the first opening and a second dielectric layer in the second opening, wherein the first dielectric layer is in contact with the first source/drain region, and wherein the second dielectric layer is in contact with a second sidewall of first nanostructure;
depositing a first dielectric feature in the first opening and on the first dielectric layer and a second dielectric feature in the second opening and on the second dielectric layer; and
growing a second source/drain region in the first opening and a third source/drain region in the second opening, wherein the second source/drain region is in contact with the first dielectric feature, and wherein the third source/drain region is separated from the second dielectric feature by an air gap.

16. The method of claim 15, wherein the first dielectric layer and the second dielectric layer are formed of a same first material and by a same first process, and wherein the first dielectric feature and the second dielectric feature are formed of a same second material and by a same second process.

17. The method of claim 16, wherein the first dielectric feature comprises a first plurality of dielectric sublayers with first physical interfaces between neighboring dielectric sublayers of the first plurality of dielectric sublayers, wherein the second dielectric feature comprises a second plurality of dielectric sublayers with second physical interfaces between neighboring dielectric sublayers of the second plurality of dielectric sublayers, and wherein the first plurality of dielectric sublayers and the second plurality of dielectric sublayers comprise the second material.

18. The method of claim 15, further comprising:
forming a third dielectric layer in the second opening, wherein the third dielectric layer is in contact with the third source/drain region and the second dielectric feature; and
forming a third dielectric feature on the third dielectric layer, wherein the third dielectric layer encircles the third dielectric feature in a cross-sectional view.

19. The method of claim 18, further comprising forming a second nanostructure over the first nanostructure, wherein an isolation feature is between the second nanostructure and the first nanostructure, wherein the second source/drain region is in contact with a first sidewall of the second nanostructure, and wherein the third source/drain region is in contact with a second sidewall of the second nanostructure.

20. The method of claim 19, wherein the third dielectric layer is in contact with the isolation feature.
